(19) United States
(12) Patent Application Publication
(10) Pub. No.: US 2012/0181165 A1
(43) Pub. Date: Jul. 19, 2012

(54) IN-SITU GAS INJECTION FOR LINEAR TARGETS

(75) Inventors: Thomas Larson Greenberg, Berkeley, CA (US); Elizabeth Dawn Lawrence, Mountain View, CA (US)

(73) Assignee: SEAGATE TECHNOLOGY LLC, Scotts Valley, CA (US)

(21) Appl. No.: 13/007,335

(22) Filed: Jan. 14, 2011

(51) Int. Cl. C23C 14/34

(52) U.S. Cl. 204/192.1; 204/298.07

(57) ABSTRACT

A system and method for in-situ introduction of gas into a vacuum deposition chamber having a target with a length/width form factor ratio greater than 1 includes a plurality of manifolds arranged around the target to deliver a gas to the vacuum chamber. A gas supply is coupled to the manifolds, and a mass flow controller couples each manifold to the gas supply. Each manifold includes a plurality of orifices for introducing gas into the vacuum chamber from the manifold. The method includes arranging a plurality of manifolds around the target, providing a gas supply to the manifolds, controlling a flow rate of the gas with a mass flow controller between each manifold and the gas supply, introducing the gas into the vacuum chamber through orifices in the manifolds, and locating the manifolds and orifices on each manifold to introduce the gas in a controlled arranged manner about the target.

### BACKGROUND

1. Field

This disclosure relates generally to vacuum deposition technology, and specifically, to the control of uniform gas injection in sputtering systems.

2. Background

In the field of gas injection for plasma sputtering systems, some prior systems inject gas for smaller areas but did not provide gas near the surface of longer targets. Others provide gas but did not fit the required form factor. A solution satisfying both requirements for uniform near surface injection for large area, long form factor targets is needed.

### SUMMARY

A system includes a vacuum chamber, a target having a length/width form factor ratio greater than 1, and a plurality of manifolds arranged around and opposite the target to deliver a gas to the vacuum chamber. A gas supply is coupled to the manifolds, and a mass flow controller is coupled to each corresponding one of the plurality of manifolds and to the gas supply. Each manifold includes a plurality of orifices for introducing gas into the vacuum chamber from the manifold.

A method of disposing gas in proximity to a target having a length/width form factor ratio greater than 1 in a vacuum chamber includes arranging a plurality of manifolds around and opposite the target, providing a gas supply coupled to the manifolds, controlling a flow rate of the gas supply to the manifolds with a corresponding mass flow controller disposed between each manifold and the gas supply, introducing the gas into the vacuum chamber through a plurality of orifices in each of the plurality of manifolds, and positioning the plurality of manifolds and the location of each of the plurality of orifices on each manifold to introduce the gas in a controlled arranged manner about the target.

A system for disposing gas in proximity to a target having a length/width form factor ratio greater than 1 in a vacuum chamber includes a means for arranging a plurality of manifolds around and opposite the target, means for providing a gas supply coupled to the manifolds, a means for controlling a flow rate of the gas supply to the manifolds with a corresponding mass flow controller disposed between each manifold and the gas supply, a means for introducing the gas into the vacuum chamber through a plurality of orifices in each of the plurality of manifolds, and a means for positioning the plurality of manifolds and the location of each of the plurality of orifices on each manifold to introduce the gas in a controlled arranged manner about the target.

### BRIEF DESCRIPTION OF THE FIGURES

Embodiments of this disclosure are illustrated by way of example and not limitation in the figures of the accompanying drawings, in which like references indicate similar elements, and in which:

FIG. 1 conceptually illustrates a system for gas injection in linear form factor targets in accordance with the disclosure.

FIG. 2A conceptually illustrates a plan view of the embodiment of the deposition chamber of FIG. 1.

FIG. 2B conceptually illustrates a cross-sectional end-view of the embodiment of the deposition chamber of FIG. 1.

FIG. 3A illustrates a mid-target manifold with orifices in accordance with the disclosure.

FIG. 3B illustrates an end-target manifold with orifices in accordance with the disclosure.

### DETAILED DESCRIPTION

Systems and methods of in-situ gas injection for linear targets for sputter deposition configured using a novel system are described. The system includes multiple mass flow controllers per target to control gas flow to the target area. mass flow controllers mounted near the vacuum chamber control gas entry via feedthroughs, gas plumbing between the mass flow controllers and points of gas injection, manifolds (internal gas lines) that surround the target length, with each internal gas line having multiple orifices having an aperture calculated to provide specific gas flow, the orifices being equally spaced along the length of manifolds to provide uniformity of gas flow over target area and a substrate to be coated with target material. By using a plurality of manifolds with multiple orifices, this differs from prior systems by allowing gas injection at linear targets without having to use too many separate parts such as nozzles.

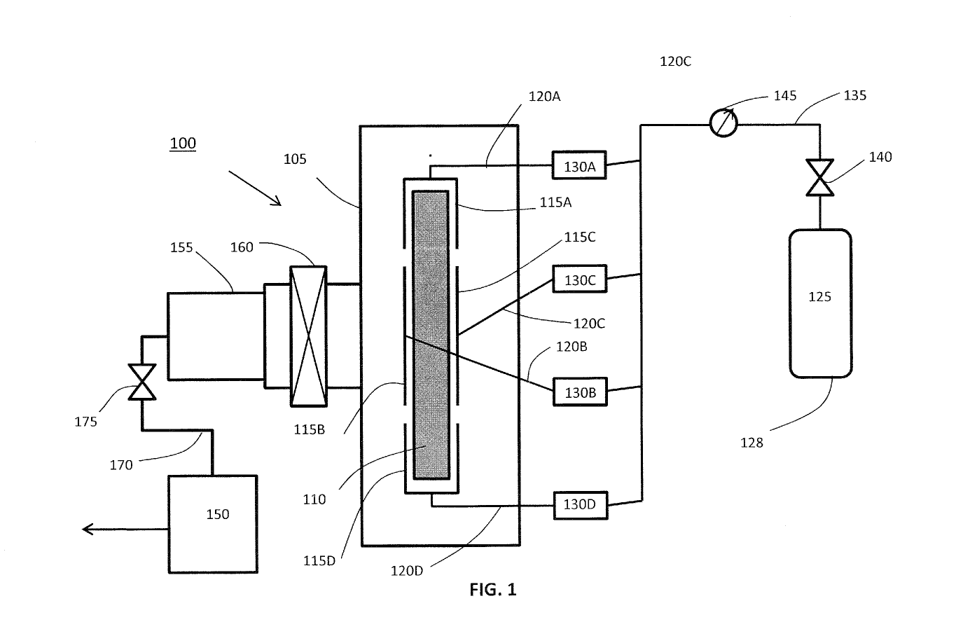

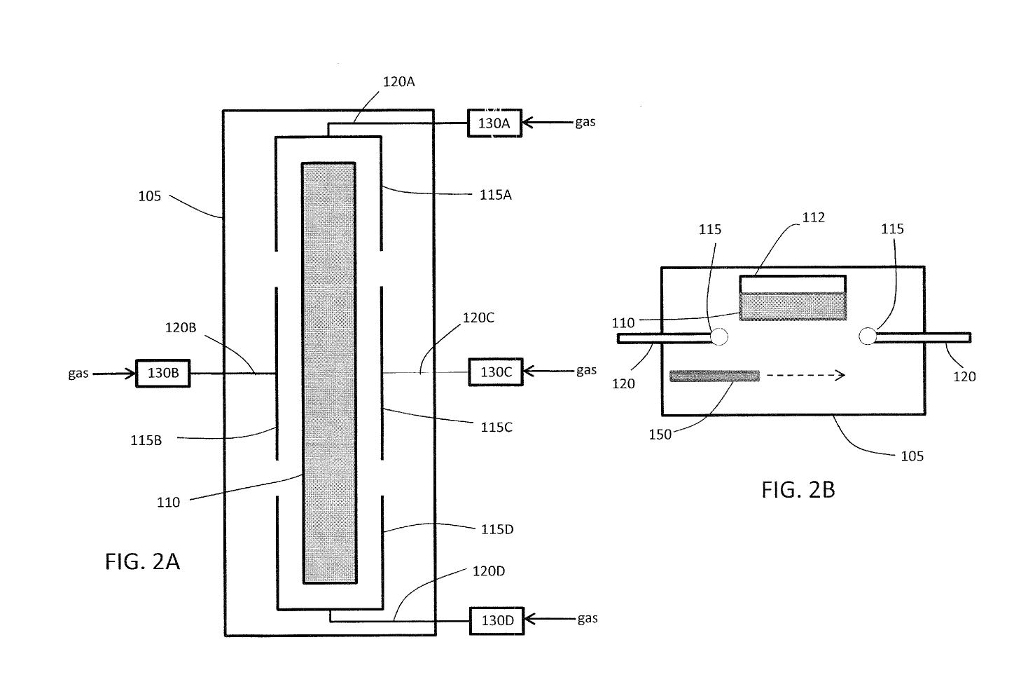

FIG. 1 illustrates a system 100 for uniform gas injection in a vacuum deposition system. FIGS. 2A and 2B conceptually illustrate views of the deposition chamber of FIG. 1, together with various components. A vacuum chamber 105 includes a target 110 a target 110 having a specified form factor of length/width ratio surrounded and apart from a plurality of manifolds 115A, 115B, 115C, 115D. As shown in FIG. 1 and FIGS. 2A and 2B, for the purpose of description, four such manifolds 115 are indicated for illustrative purposes without loss of generality, but a larger or smaller plurality of manifolds 115 may be included. Manifolds 115A and 115D are end-target manifolds, whereas manifolds 115B and 115C are mid-target manifolds. The manifolds 115 are hollow tubes positioned around and apart from the target 110 for uniform introduction of gas into the vacuum chamber 105 near the surface of the target 110. Gas is introduced into the manifolds 115A, 115B, 115C, 115D via feedthrough lines 120A, 120B, 120C, 120D respectively. Each of the feedthrough lines 120A, 120B, 120C, 120D passes into the vacuum chamber 105 and is fed gas from a respective mass flow controller (MFC) 130A, 130B, 130C, 130D. The feedthoughs line 120 may include feedthroughs (not shown) that may be, for example Conflats, VCO, VCR, a combination of the foregoing, or the like. In some embodiments, for example, the Conflat feedthrough may have a Swagelok fitting on the inside of the chamber and a VCR on the outside, or similar other combinations.

Referring to FIG. 1, gas flow is urged through the vacuum chamber 105 by a high vacuum pump 155 coupled to the vacuum chamber 105 via an isolation valve 160. The vacuum pump 155 is coupled to a mechanical pump 150 via a fore line 170 that may include a fore line valve 175. Gas pumped by the mechanical pump 150 may then be exhausted thereform.

All MFCs 130A, 130B, 130C, 130D may be fed gas from one or more gas sources 125 via a gas feed line 135, wherein the gas feed line 135 may further include a valve 140 and a regulator 145. In another embodiment, the gas source 125 may be a single source in a single tank 128. In an alternative embodiment (not shown), the gas source may be a plurality of gas sources 125, each in a respective tank 128, in which case each tank 128 may have a respective valve 140 and regulator 145 connected to a common feed line 135. Gas flow through the vacuum chamber 105 is coerced by pumping from a mechanical pump 150 and high vacuum pump 155 through an isolation valve 160.

The manifolds 115 fit in the vacuum chamber 105 around the target 110 and in a plane spaced apart from the surface of the target 110. Referring to FIG. 2B, the target is supported on a base 112 within the vacuum chamber 105. A substrate 150 to be coated by plasma sputter deposition with material from the target 110 may be positioned opposite the target 110, or alternatively, may be transported past the face of the target 110 during the deposition process.

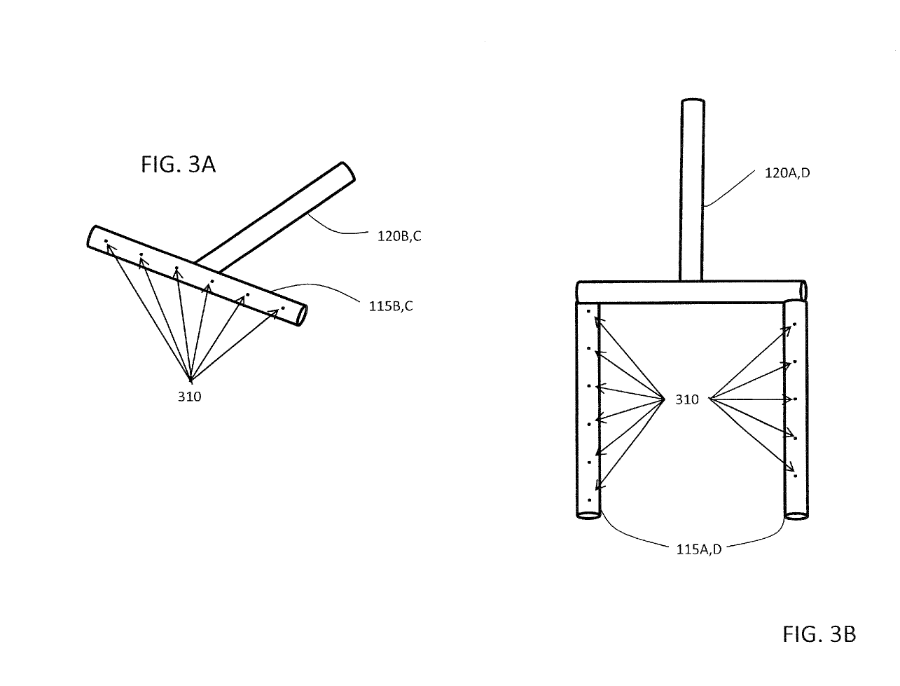

FIG. 3A illustrates a mid-target manifold 115B, 115C, and FIG. 3B illustrates an end-target manifold 115A, 115D. The manifolds 115 include a plurality of orifices 310. The manifolds 115 are arranged around the target 110 and the orifices 310 may be arranged on the manifolds 115 so that the spacing of orifices 310 around the space opposite the target is uniform. Thus, a distribution of gas across the surface of the target 110 may be controlled, and made uniform or to have a selected flow rate and concentration as a function of position along the length (i.e., a long dimension) of the target 110. In one embodiment, each manifold has six orifices. The size of each orifice in the example may be determined from calculations and testing.

For example, the molecular mean free path may be calculated (for a single molecule gas or a gas mixture (reference equation 6.16 Introduction to Physical Gas Dynamics, Vincenti, Kruger). The mean free path may then be divided by the hole size to find a value of Knudsen number. The Knudsen number may determine whether to use continuum or molecular flow equations to determine flow rates (reference A User's Guide to Vacuum Technology, O'Hanlon). After reviewing the calculations for different hole sizes, for example, an orifice diameter may be selected to provide a gas flow rate of approximately 10 standard cubic centimeters per minute (sccm) per orifice 310.

The mass flow controllers (MFC 130) are added to the input of each manifold 115 to provide low pressure upstream of the orifices 310 and control an accurate gas flow. The MFC 130 for each line must have a full scale capacity to handle a selected number of orifices of the selected size. Thus, for example, if each of the MFCs 130 has a full scale capacity of 100 sccm, that would be at least adequate to cover 6 orifices designed to flow gas at 10 sccm each.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application system while maintaining substantially the same functionality without departing from the scope and spirit of the present invention. In addition, although the preferred embodiment described herein is directed to a particular set of manifolds with orifices for controlled introduction of gas into a vacuum chamber, it will be appreciated by those skilled in the art that the teachings of the present invention can be applied to other gas handling systems without departing from the scope and spirit of the present invention.

1-21. (canceled)

22. A system comprising:
one or more manifolds arranged to provide a substantially uniform distribution of gas to a target in a vacuum chamber.

23. The system of claim 22, wherein each of the one or more manifolds comprises one or more orifices to provide the uniform distribution of the gas to the target.

24. The system of claim 22, wherein the target comprises a length/width form factor ratio greater than 1.

25. The system of claim 22, further comprising a substrate configured to be arranged with the target.

26. The system of claim 25, wherein the substrate is configured to be transported in a plane across and apart from a surface of the target.

27. The system of claim 26, further comprising a plasma discharge system to excite a plasma in the gas in proximity to the target.

28. The system of 27, wherein the one or more manifolds are further arranged such that material from the target is sputtered from a surface of the target and deposited on the substrate in the presence of the plasma.

29. A system comprising:
a vacuum chamber; and
one or more manifolds arranged to substantially surround a target in the vacuum chamber.

30. The system of claim 20, wherein the one or more manifolds are arranged to provide a substantially uniform distribution of gas to the target.

31. The system of claim 39, wherein each of the one or more manifolds comprises one or more orifices to provide the uniform distribution of the gas to the target.

32. The system of claim 29, wherein the target comprises a length/width form factor ratio greater than 1.

33. The system of claim 29, further comprising a substrate configured to be arranged with the target.

34. The system of claim 33, wherein the substrate is configured to be transported in a plane across and apart from a surface of the target.

35. The system of claim 33, further comprising a plasma discharge system to excite a plasma in the gas in proximity to the target.

36. The system of claim 34, wherein the one or more manifolds are arranged such that material from the target is sputtered from a surface of the target and deposited on the substrate in the presence of the plasma.

37. A method to provide a substantially uniform distribution of gas to a target in a vacuum chamber comprising:
introducing the gas into the vacuum chamber through a plurality of orifices located in each of a plurality of manifolds, wherein each of the plurality of manifolds and each the plurality of orifices are configured to introduce the gas in a uniform manner.

38. The method of claim 37, wherein the target has a length/width form factor ratio greater than 1.

39. The method of claim 37, further comprising locating a substrate opposite the target and the plurality of manifolds.

40. The method of claim 39, further comprising transporting the substrate in a plane opposite a surface of the target.

41. The method of claim 39, further comprising:
exciting a plasma discharge in the gas in proximity to the target; and
sputtering material from the surface of the target to the substrate during the plasma discharge.

42. The method of claim 37, further comprising providing the gas from a gas supply coupled to the manifolds.

43. The method of claim 42, further comprising controlling the flow rate with a corresponding mass flow controller disposed between each manifold and the gas supply.

44. A system for disposing a gas in proximity to a target within a vacuum chamber comprising:
means for introducing the gas into the vacuum chamber to dispose the gas in a uniform manner about the target.

45. The system of claim 44, wherein the target comprises a length/width form factor ratio greater than 1.
